(19) United States
(12) Patent Application Publication
(10) Pub. No.: US 2010/0255641 A1
(43) Pub. Date: Oct. 7, 2010

(54) Semiconductor Manufacturing Method

(75) Inventors: Noboru NAKANISHI, Beppu-shi (JP); Kazunori HAYATA, Beppu-shi (JP); Mutsumi MASUMOTO, Beppu-shi (JP)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED

(21) Appl. No.: 12/756,053

(22) Filed: Apr. 7, 2010

(30) Foreign Application Priority Data
Apr. 7, 2009 (JP) 2009-093183

(51) Int. Cl. H01L 21/56

(52) U.S. Cl. 438/127; 257/E21.502

(57) ABSTRACT

The objective of this invention is to present a semiconductor device manufacturing method with which the formation of voids inside an underfill resin can be prevented using a simple configuration. The semiconductor device manufacturing method of the present invention involves a step in which multiple electrodes formed on one principal surface of each semiconductor chip 20 are flip-chip bonded to corresponding conductive areas formed on a substrate, a step (condition 1) in which liquid underfill resin 40 is supplied along the circumferences of semiconductor chips 20 mounted on the substrate in the atmospheric pressure so as to form air pocket 110 between each semiconductor chip 20 and substrate 30, a step (conditions 2, 3, 4) in which the substrate is transferred from the atmospheric pressure into a vacuum atmosphere in order to discharge the air from air pockets 110, and a step (conditions 5, 6, 7, 8) in which the substrate is transferred from the vacuum atmosphere into the atmospheric pressure in order to let underfill resin 40 advance deep in the semiconductor chips.

### FIELD OF THE INVENTION

The present invention pertains to a semiconductor manufacturing method. In particular, it pertains to a technique for forming an underfill resin layer between semiconductor chips and a substrate that are flip-chip bonded together.

### BACKGROUND OF THE INVENTION

As portable telephones, portable computers, and other compact electronic equipment become more sophisticated, higher levels of integration of semiconductor chips to be installed in the electronic equipment and reduction of the pitch among them are required. Flip-chip mounting for connecting bare chips to a substrate is one technology for mounting semiconductor chips in an integrated manner at a narrow pitch. With flip-chip mounting, bump electrodes formed on a principal surface serving as an integrated circuit surface of each semiconductor chip are connected directly to electrodes or lands formed on the substrate face to face. Flip-chip mounting replaces wire bonding.

A method in which bare chips with bumps are pressure-bonded to a substrate laminated with an anisotropic conductive film and a method in which bare chips with solder bumps are mounted on a substrate and connected by means of reflow are available for flip-chip mounting. In the latter case, to prevent a fracture that would occur if stress is concentrated on a solder bump, an underfill resin is injected between the bare chips and the substrate in order to mitigate the stress.

Patent literature 1 pertains to a semiconductor device manufacturing method involving the injection of an underfill resin. In order to solve a problem in which the resin adheres to the upper surface of the semiconductor chips, a plasma treatment is applied to the upper surface of the semiconductor chips after the underfill resin is sealed off. As a result, heat spreaders can be connected easily to the upper surface of the semiconductor chips, whereby their radiation performance can be improved.

Patent literature 2 discloses a method in which in order to prevent the formation of voids such as air bubbles inside the underfill resin, the underfill resin is injected between the semiconductor chips and the substrate in a vacuum, and the substrate injected with the underfill resin is subsequently exposed to the atmospheric pressure.

[Patent literature 1] Japanese Kokai Patent Application No. 2005-217295
[Patent literature 2] Japanese Kokai Patent Application No. 2007-103772

### SUMMARY OF THE INVENTION

As shown in Patent literature 2, when the underfill resin is injected in a vacuum, a dispenser for injecting the underfill resin must be provided inside a vacuum chamber. The dispenser must be equipped with a mechanism that allows it to be positioned properly with respect to the semiconductor chips mounted on the substrate. Furthermore, restrictions are imposed upon the underfill injection mechanism of the dispenser due to the fact that it is to be used in a vacuum. Thus, injection of the underfill resin in the vacuum results in problems that the equipment becomes large, and the cost is increased. Furthermore, because volatile components of the underfill resin material cannot stand for a long period of time in a vacuum, the service life of the resin is shortened.

The objective of the present invention is to present a semiconductor device manufacturing method that allows injection of an underfill resin using a simple equipment while preventing the formation of voids such as air bubbles in order to solve the aforementioned conventional problems.

The semiconductor device manufacturing method involves a first step in which multiple electrodes formed in a 2-dimensional pattern on one of the principal surfaces of each semiconductor chip are bonded to corresponding conductive areas formed on a substrate, a second step in which a liquid underfill resin is supplied along the circumferences of the semiconductor chips mounted on the substrate in the atmospheric pressure so as to form an air pocket between each semiconductor chip and the substrate, a third step in which the substrate bonded with the aforementioned semiconductor chips is transferred from the atmospheric pressure into a vacuum in order to discharge air from the air pockets, and a fourth step in which the substrate bonded with the semiconductor chips is transferred from the vacuum into the atmospheric pressure in order to let the underfill resin advance deeply into the gaps between the semiconductor chips and the substrate.

Preferably, in the second step, a wall part is formed between the semiconductor chip and the substrate by the underfill resin, and the air pocket is formed in the space surrounded by the wall part. Preferably, in the third step, the air in the air pocket is discharged to the outside through a path formed on the underfill resin wall part. Preferably, in the third step, the substrate supplied with the underfill resin in the atmospheric pressure is transferred into a vacuum chamber, which is then evacuated. Preferably, the first step is carried out at a first temperature that is higher than room temperature, and the second through the fourth steps are carried out while the first temperature is maintained.

Furthermore, the manufacturing method may include a fifth step in which the semiconductor chips and the substrate are kept at a temperature that is higher than the glass transition temperature of the aforementioned underfill resin for a prescribed period of time after the fourth step. Preferably, the first temperature is approximately 100° C., the underfill resin is an epoxy resin with a viscosity of approximately 0.5 (Pas) or lower at 80-100° C.

### BRIEF DESCRIPTION OF THE DRAWINGS

FIG. 1 is a flow chart showing steps for manufacturing a flip-chip mounted semiconductor device pertaining to an embodiment of the present invention.

FIG. 2 is a perspective view showing multiple semiconductor chips that are flip-chip bonded to a substrate.

FIG. 3 shows diagrams of cross-sectional views of a semiconductor chip and a substrate that are flip-chip bonded together.

FIG. 4 is a flow chart showing steps for supplying an underfill resin.

FIG. 5 shows transitions from formation of an air pocket that is captured by an underfill resin in the atmospheric pressure to evacuation of the air from the air pocket in a vacuum, movement of the underfill resin under the atmospheric pressure, and reduction of the air pocket space.

FIG. 6 is a graph showing characteristics of an underfill resin.

FIG. 7 shows another semiconductor device created using a manufacturing method pertaining to an embodiment of the present invention.

FIG. 8 shows another semiconductor device created using a manufacturing method pertaining to an embodiment of the present invention.

FIG. 9 is a diagram showing an example semiconductor manufacturing equipment used for flip-chip mounting.

### REFERENCE NUMERALS AND SYMBOLS AS SHOWN IN THE DRAWINGS

In the figures, 10 represents a semiconductor device, 20 a semiconductor chip, 22 a principal surface, 24 an electrode, 26 a bump, 30 a substrate, 32 an electrode, 34 a bump, 36 an internal wire, 38 an external electrode, 40 an underfill resin, 40A a wall part of the underfill resin, 40B a path at the wall part, 200 a semiconductor package, 210 a substrate, 220 an underfill resin, 300 a first semiconductor package, 400 a second semiconductor package, 420 an underfill resin, 500 a manufacturing device, 510 a loader, 520 a flip-chip stage, 530 an underfill stage, 532 a dispenser, and 534 a vacuum chamber.

### DESCRIPTION OF THE EMBODIMENTS

According to the present invention, because the underfill resin is supplied in the atmospheric pressure, the underfill resin can be supplied using a tool that is simpler than that used in the past. In addition, because the air pocket is formed when the underfill resin is applied, and the air inside the underfill resin can be discharged to the outside when the assembly is transferred into a vacuum, the formation of air bubbles inside the underfill resin can be prevented. Furthermore, because the air space inside the underfill resin is eliminated almost completely upon reverting back to the atmospheric pressure from the vacuum, the formation of voids inside the underfill resin can be prevented.

Furthermore, because the steps for bonding the semiconductor chips to the substrate through the step for supplying the underfill resin are carried out at an elevated temperature, a good connection between the semiconductor chips and the substrate can be maintained. And because the underfill resin is not exposed to the atmospheric pressure for too long, deterioration of the underfill resin can be prevented.

Preferred embodiments of the present invention will be explained in detail below with reference to figures. Here, be advised that sizes, shapes, and scales used in the figures are accentuated in order to facilitate understanding of the invention, and they do not always match those of actual products.

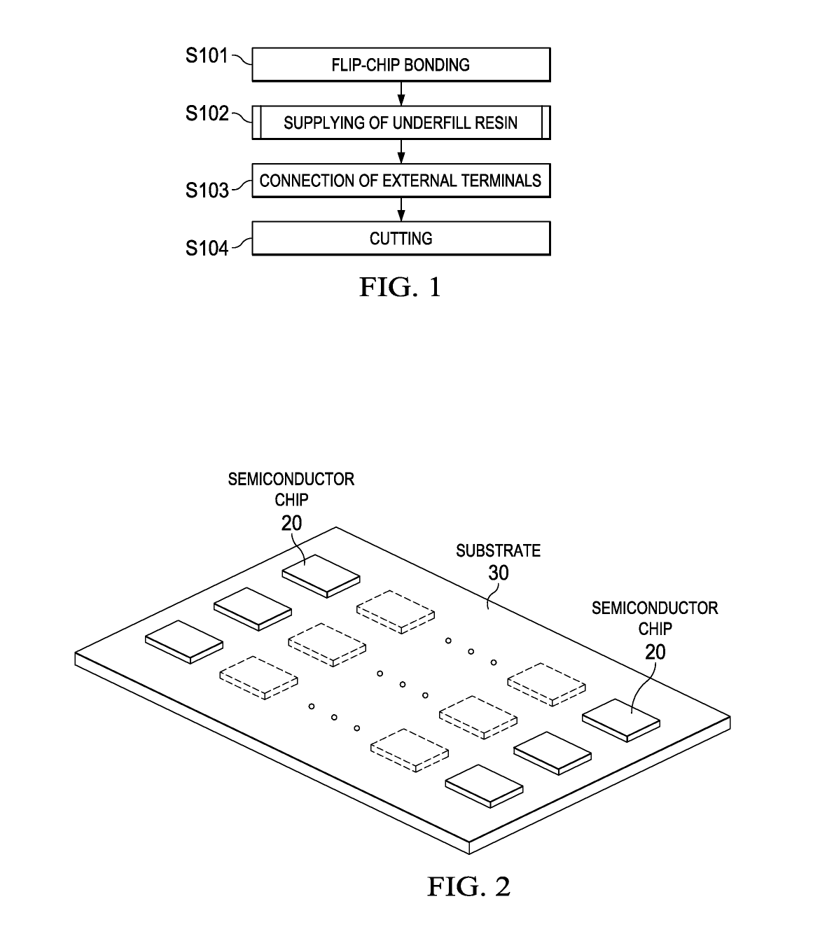

FIG. 1 is a flow chart depicting steps for manufacturing a flip-chip mounted semiconductor device according to an embodiment of the present invention. Rectangular semiconductor chips are cut from a silicon wafer on which circuit elements are formed, and the cut semiconductor chips are positioned such that electrodes formed on their circuit-side surfaces face a substrate. Then, the electrodes of the semiconductor chips are connected to bump electrodes formed on the substrate by means of ultrasonic vibration. As a result, the electrodes of the semiconductor chips are flip-chip bonded to conductive areas formed on the substrate (step S101). The flip-chip bonding is carried out while the semiconductor chips and the substrate are held at an elevated temperature.

FIG. 2 depicts a condition in which multiple semiconductor chips are flip-chip bonded to a substrate. Individual semiconductor chips 20 cut from a silicon wafer are flip-chip bonded to substrate 30 while aligned in an orderly manner.

Next, a liquid underfill resin is applied along the circumferences of the respective semiconductor chips disposed on the substrate (step S102). As will be described later, the underfill resin is supplied under atmospheric pressure, followed by transferring the assembly into a vacuum before reverting back to the atmospheric pressure. The formation of voids such as air bubbles inside the underfill resin is prevented by the atmospheric pressure—vacuum—atmospheric pressure in order to reinforce the bonding between them.

Next, external terminals, such as bumps, are connected to the back surface of the substrate, that is, the surface opposite the surface where the semiconductor chips are bonded, (step S103). Finally, the semiconductor chips are singulated in order to obtain individual semiconductor devices (step S104).

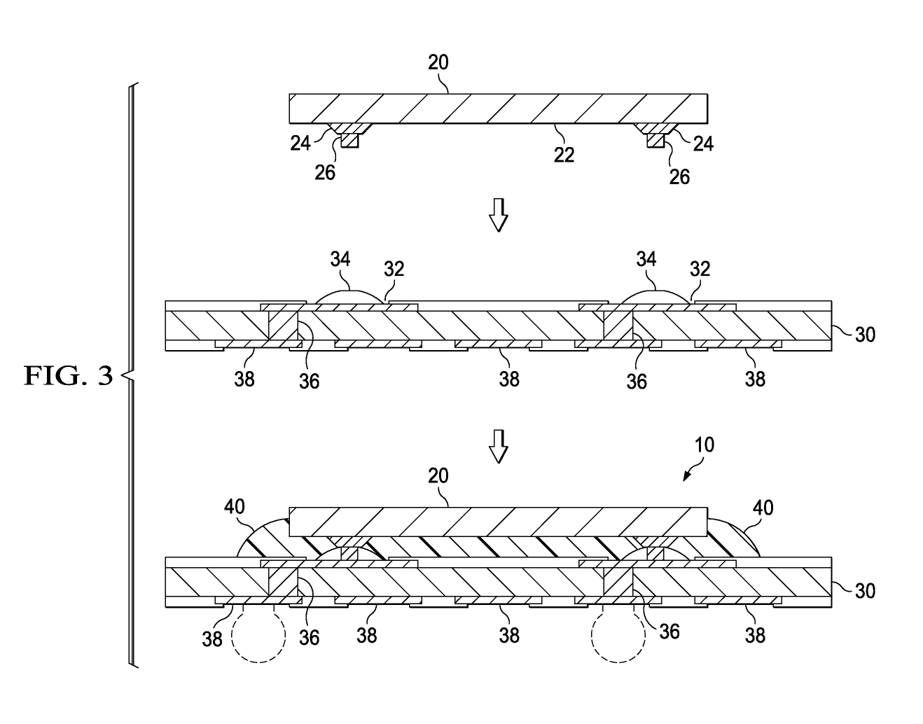

FIG. 3 depicts cross-sectional views of a semiconductor chip and a substrate flip-chip bonded together. As depicted in the figure, multiple aluminum electrode pads 24 are formed in a 2-dimensional pattern on a principal surface 22 of a semiconductor chip 20. Protrusive bumps 26 are connected to electrode pads 24. Bumps 26 are Au bumps, for example; and their diameter is approximately 35 μm. Electrode pads 24 are disposed at a 50 μm pitch, for example.

Cu electrodes 32 serving as conductive areas are formed on the upper surface of substrate 30, and Au bumps 34 are formed on electrodes 32. Bumps 34 are formed at the positions corresponding to electrode pads 24 or bumps 26 of semiconductor chip 20. Electrodes 32 can be connected to external electrodes 38 formed on the back surface of the substrate 30 via internal wires 36. External electrodes 38 are solder balls for BGA or CSP.

Preferably, ultrasonic vibration is applied while bumps 26 of semiconductor chip 20 are pressed against bumps 34 of substrate 30 to achieve metal-metal bonding of bumps 26 and bumps 34. Because the bonding of bumps 26 and bumps 34 is fragile, underfill resin 40 is supplied into a space formed between principal surface 22 of semiconductor chip 20 and substrate 30 using a method to be described later. The space between semiconductor chip 20 and substrate 30 should be 15 μm or less, preferably 7 μm.

As described above, flip-chip bonding is carried out while the semiconductor chip and the substrate are heated to a prescribed temperature, for example, approximately 100° C. The semiconductor chip cut out of a silicon wafer and the substrate (for example, a substrate made of an organic material) have different thermal expansion coefficients. As such, if the temperature at the time of the flip-chip bonding and the temperature at the time of supply of the underfill resin are substantially different, the metal-metal bonding between the semiconductor chip and the substrate is weakened due to the difference between their thermal expansion coefficients, which must be prevented.

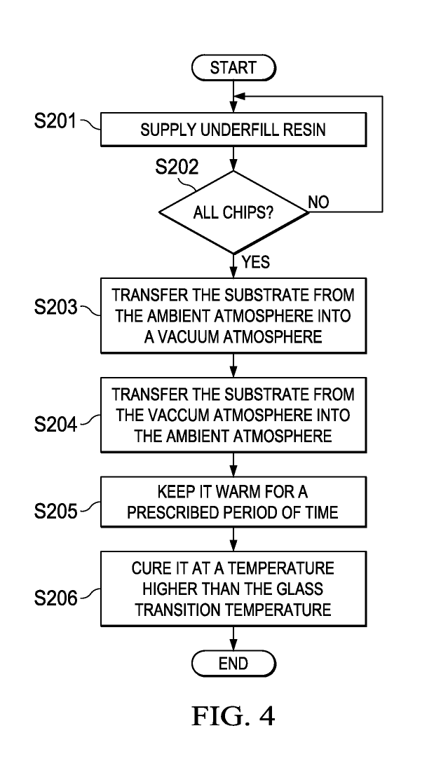

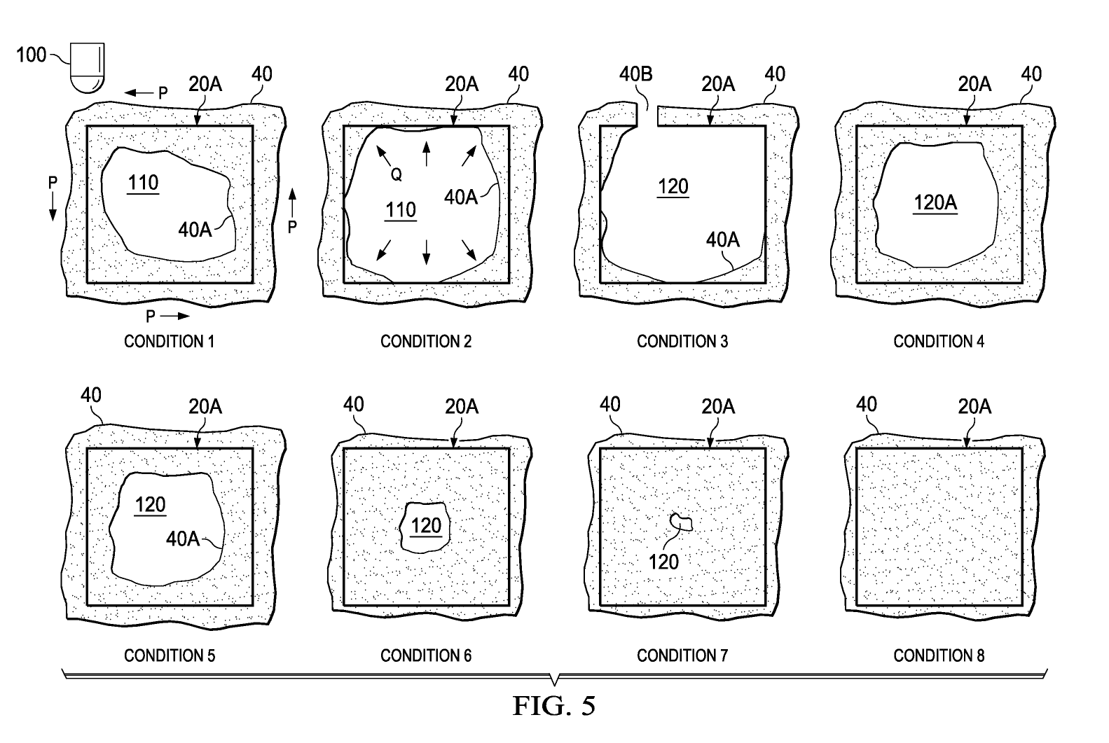

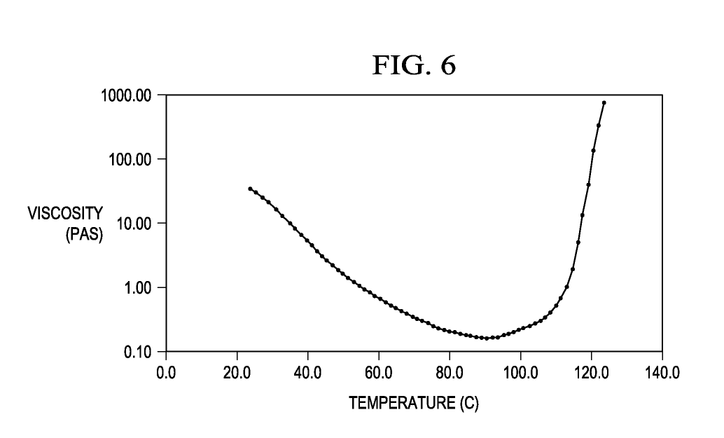

Next, detailed steps for supplying the underfill resin are shown in FIGS. 4 and 5. Once flip-chip bonded with semiconductor chip 20, substrate 30 is kept in the atmospheric pressure while it is held at approximately 100° C. Next, liquid underfill resin is applied to the semiconductor chip using a dispenser (step S201). Condition 1 in FIG. 5 shows a condition in which underfill resin 40 is applied to a semiconductor chip 20, wherein square line 20A represents the outline of the semiconductor chip, and shaded area 40 represents the underfill resin.

Supply nozzle 100 of the dispenser scans in the directions indicated by P along the four sides of semiconductor chip 20 while applying a constant amount of liquid underfill resin. Supply nozzle 100 may include a heating member such as a heater in order to keep the underfill resin at a constant temperature. When the underfill resin is heated, it becomes liquefied, gains a certain level of viscosity, and advances through the space formed between the semiconductor chip and the substrate toward the interior of the semiconductor chip due to capillary action. As a result, air pocket 110 is formed inside a space surrounded by the surface of semiconductor chip 20, the upper surface of substrate 30, and wall part 40A formed by underfill resin 40.

Preferably, underfill resin 40 is composed of an epoxy resin with a low level of viscosity at the constant temperature, and Namix U8437-48, for example, may be used. FIG. 6 is a graph depicting the characteristics of an epoxy resin, wherein the horizontal axis represents temperature, and the vertical axis represents viscosity (Pas). As is clear from the graph, epoxy resin exhibits an inflection point where the viscosity is at a minimum at approximately 90° C. The temperature of the supplied epoxy resin is adjusted to remain approximately at 80-100° C. The 80-100° C. epoxy resin has a low level of viscosity, that is, approximately 0.5 (Pas), so it can move smoothly between semiconductor chips disposed at a narrow pitch and a narrow spacing.

The underfill resin is supplied to all the semiconductor chips mounted on the substrate (step S202). Once underfill resin is applied to all the semiconductor chips, the substrate is transferred from the atmospheric pressure into a vacuum atmosphere (step S203). This step is carried out by transferring the substrate into a vacuum chamber. At this time, the substrate is transferred into the vacuum atmosphere while the temperature used when the underfill resin was supplied is maintained. For example, the substrate is supported using a temperature-controlled arm or stage when it is transferred into the vacuum chamber.

The pressure in the vacuum chamber maybe evacuated to approximately 1 torr in approximately 1 min. This degree of vacuum and the evacuation time are mere examples, and these numeric values do not impose any restrictions. As the evacuation begins, as shown in condition 2 in FIG. 5, air pocket 110 expands outward due to pressure difference Q between the vacuum outside underfill resin 40 and the air pocket 110. Then, as shown in condition 3, as air pocket 110 further expands, a part of wall part 40A formed by the surrounding underfill resin maybe broken, and a path 40B is formed there. Then, the air in air pocket 110 is discharged to the outside through path 40B, and the inner space 120 surrounded by wall part 40A becomes a vacuum. Wall part 40A formed by underfill resin 40 then contracts somewhat in response to the evacuation of air pocket 110, and the path 40B disappears as wall part 40A becomes reconnected. Now the inner space 120A becomes surrounded by wall part 40A formed by underfill resin 40, and this condition is maintained as shown in condition 4.

Next, the vacuum chamber is pressurized to revert the substrate from under vacuum to under atmospheric pressure (step S204). Once the inside of vacuum chamber returns to the atmospheric pressure, as shown in condition 5 in FIG. 5, the atmospheric pressure acts upon the outer circumference of underfill resin 40, and wall part 40A of underfill resin 40 moves inward in a direction of contraction. Because underfill resin 40 is held at approximately 80-100° C. and it exhibits a low level of viscosity, wall part 40A moves deeply into the semiconductor chip due to the atmospheric pressure. Then, as shown in conditions 6 and 7, inner space 120 gradually becomes smaller, and inner space 120 ultimately disappears completely as shown in condition 8. The space formed between the semiconductor chip and the substrate is filled in completely by underfill resin 40 in this manner. Because inner space 120 is at first in a vacuum state without any air, no voids, such as air bubbles, are formed inside underfill resin 40.

Once filled with the underfill resin through this process, the substrate is held at the elevated temperature of approximately 100° C. for a prescribed period of time (step S205). When the substrate is kept warm for the prescribed period of time, transition of underfill resin 40 from condition 5 to 8 is assured in order to eliminate inner space 120 almost completely. Next, the substrate temperature is increased to a temperature higher than the glass transition temperature of underfill resin 40 and this temperature is held for a prescribed period of time in order to cure the substrate (step S206). For example, the substrate is heated to approximately 150° C. and cured for approximately 1 hour.

In the present embodiment, the underfill resin is supplied to the outer circumference of the semiconductor chip so as to capture air under the atmospheric pressure. The substrate is then transferred into a vacuum to discharge the captured air completely, and the substrate is returned to the atmospheric pressure once again in order to eliminate the inner space surrounded by the underfill resin. As a result, formation of air bubbles and voids inside the underfill resin can be prevented, and firm bonding between the semiconductor chip and the substrate can thus be improved. This is because the underfill resin that contains no voids so invasion of moisture from the outside can be prevented effectively.

Furthermore, because the underfill resin can be applied in atmospheric pressure, a dispenser no longer needs to be provided inside the vacuum chamber, so the configuration of the dispenser for supplying the underfill resin can be simplified significantly. Therefore, an existing dispenser that can be used in the atmospheric pressure can be used as is. As a result, the cost of the flip-chip mounting device can be reduced significantly.

The configurations of the semiconductor chip and the substrate explained in the embodiment are mere examples, and they do not impose any restrictions. For example, bumps 26 formed on principal surface 22 of semiconductor chip 20 may be gold-plated bumps or Au stud bumps, or they may be solder or solder balls of other kinds. Solder bumps can be formed by means of plating or printing. Lead-free solder, such as Ag/Sn, can be used as the solder. In this case, solder bumps do not have to be formed on the electrodes of the substrate.

A polyamide substrate or a ceramic substrate can be used as substrate 30, and the substrate may have a multi-layered structure. Moreover, the underfill resin may be a resin other than an epoxy resin. To obtain a multi-chip module, a substrate may be diced with multiple semiconductor chips as a group.

Next, a modified example of the flip-chip connection will be described. Although an example in which semiconductor chip 20 as a bare chip was flip-chip mounted on substrate 30 in this embodiment, a semiconductor package may be mounted instead of a semiconductor chip.

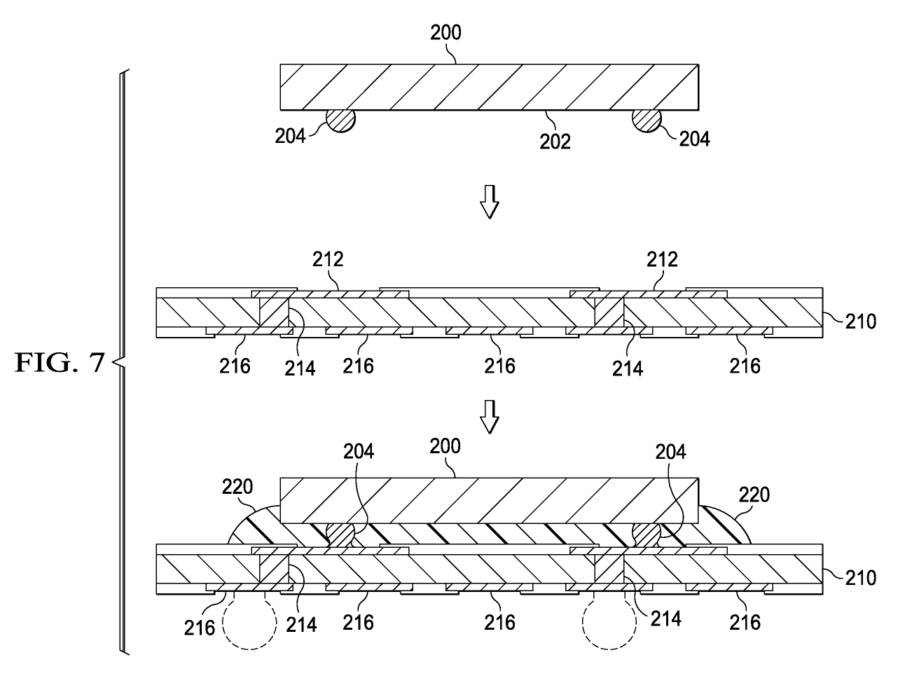

FIG. 7 shows cross-sectional structures in which such surface mount semiconductor package 200 as a BGA or CSP is mounted on substrate 210. Semiconductor package 200 is equipped with multiple external terminals 204 that are arranged in a 2-dimensional pattern on back surface 202 of the package. External terminals 204 are solder balls, for example. Multiple external terminals 204 are bonded to conductive lands 212 that are formed on the upper surface of substrate 210, and underfill resin 220 is then filled into a space formed between rear surface 202 of the package and substrate 210. Underfill resin 220 is applied according to the process shown in FIG. 4 in the same manner as that in the aforementioned embodiment.

External electrodes 216 of substrate 210 are connected to conductive lands 212 via internal wires 214, and external terminals 204 of semiconductor package 200 are connected to conductive lands 212. Bumps may be connected to external terminals 216 of substrate 210. When the underfill resin is filled between semiconductor package 200 and substrate 210 in a vacuum in this manner, formation of voids and air bubbles in the underfill resin can be prevented, so the bonding strength between the semiconductor and the electrodes of the substrate can be improved.

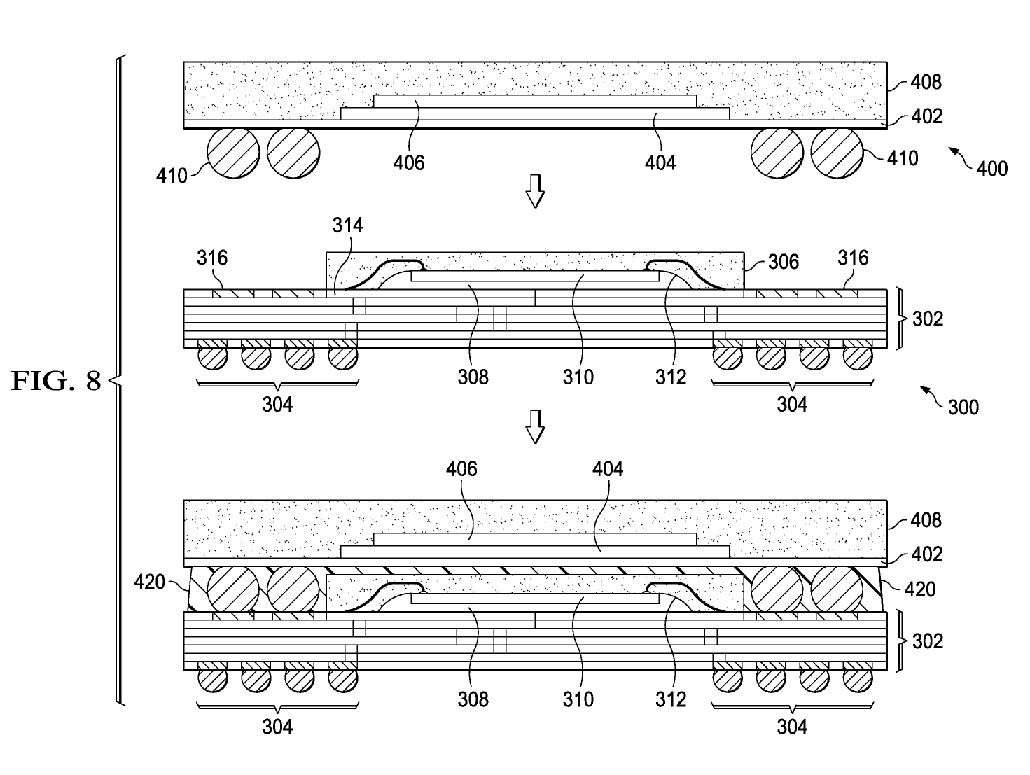

Furthermore, the semiconductor device may have a package-on-package (PoP) structure in which another semiconductor package is mounted on top of a semiconductor package. FIG. 8 depicts cross-sections of a semiconductor device with a PoP structure in which a BGA package is layered on top of a BGA package.

First semiconductor package 300 has multi-layered substrate 302, multiple solder balls 304 that are formed on the back surface of multi-wiring substrate 302, and mold resin 306 that is formed over the upper surface of multi-wiring substrate 302. Semiconductor chip 310 is attached to the upper surface of substrate 302 via die attach 308, and electrodes of semiconductor chip 310 are connected to copper patterns 314 that are formed on the substrate using bonding wires 312. The area that contains semiconductor chip 310 and bonding wires 312 is sealed off using mold resin 306.

Second semiconductor package 400 is disposed on top of first semiconductor package 300. In the second semiconductor package 400, semiconductor chips 404 and 406 are stacked on the upper surface of substrate 402, and these semiconductor chips 404 and 406 are sealed off using mold resin 408. Two rows of solder balls 410 are formed on the back surface of substrate 402 in the four directions.

Solder balls 410 are disposed such that they surround mold resin 306 when second semiconductor package 400 is mounted on first semiconductor package 300, and they are connected to electrodes 316 that are formed on the upper surface of substrate 302. Next, underfill resin 420 is supplied into a space that is formed between the first semiconductor package 300 and the second semiconductor package 400. As described above, the underfill resin is supplied in the atmospheric pressure, then transferred into a vacuum, and reverted back to the atmospheric pressure. As a result, the bonding strength between solder balls 410 of the first and second packages and electrodes 316 can be improved, whereby fracturing can be prevented.

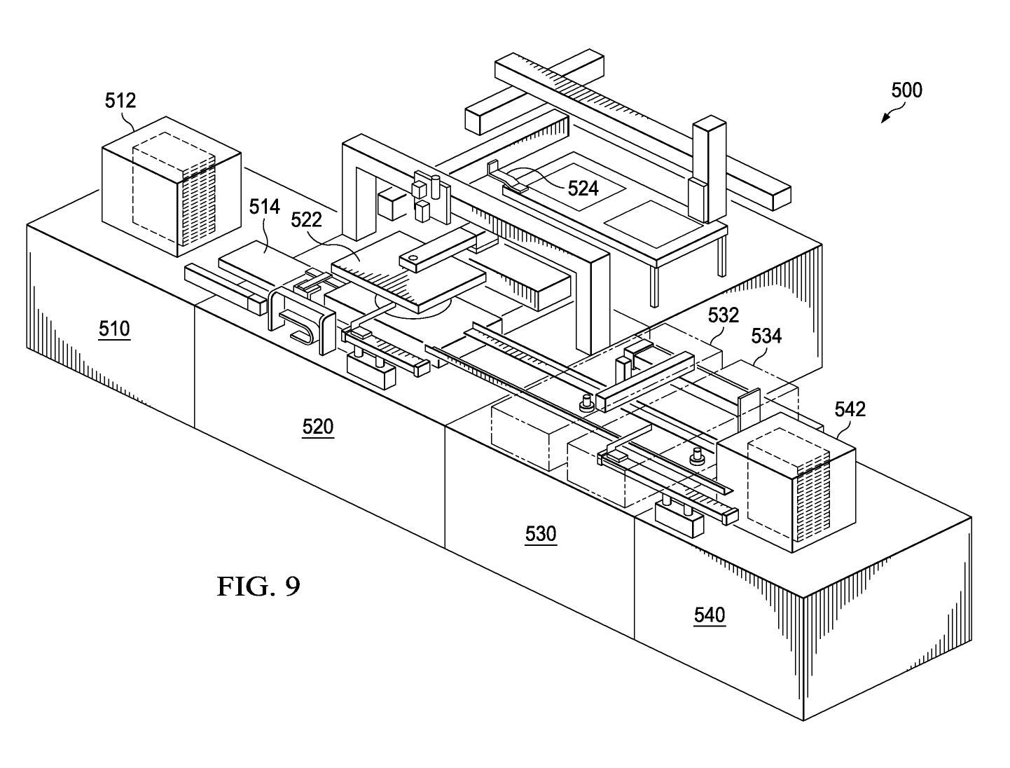

FIG. 9 is a perspective view depicting an outlined configuration of a piece of semiconductor manufacturing equipment used for flip-chip mounting. This manufacturing equipment 500 is configured with the inclusion of loader 510 for housing multiple substrates, flip-chip stage 520 for bonding semiconductor chips to a substrate, underfill stage 530 for supplying an underfill resin to the substrate, and the unloader stage 540 for housing multiple flip-chip bonded substrates. Loader stage 510 includes loader 512 for stacking multiple substrates 30 in the vertical direction, and loader 512 is heated to a prescribed temperature using a heater (not shown.) Once substrate 30 is removed from loader 512, its temperature is adjusted at preheating stage 514 and it is conveyed to flip-chip stage 520 while its temperature is maintained.

Next, substrate 30 is mounted on heat block 522, which keeps substrate 30 at the temperature required for flip-chip bonding. Then, semiconductor chips 20 are removed from chip tray changer 524 by a chip mounter and are disposed at proper positions on substrate 30. Bumps 26 of semiconductor chips 20 are bonded to bumps 34 of substrate 30 by means of ultrasonic vibrations.

Next, using dispenser 532, the underfill resin is applied in the atmospheric pressure to the semiconductor chips mounted on the substrate. Next, the substrate is transferred into vacuum chamber 534 while the temperature and vacuum are maintained. After a prescribed period of time has passed, the chamber is reverted to the atmospheric pressure, and the condition is maintained for a prescribed period of time. Next, the substrate is removed from the chamber and cured for a prescribed period of time while it is placed on a heat block (not shown.) Finally, substrates 30 are stacked in unloader 140.

Preferred embodiments of the present invention have been explained above. However, the specific embodiments do not impose any restrictions, and the present invention can be modified or changed in a variety of ways within the scope of the present invention described under Claims.

The semiconductor device manufacturing method pertaining to the present invention can be used for surface mounting of miniaturized high-density, narrow-pitch semiconductor chips and semiconductor devices.

1. A semiconductor manufacturing method, comprising:
supplying under atmospheric pressure a liquid underfill resin along circumferences of a semiconductor chip bonded on a substrate;
forming an air pocket space between the semiconductor chip, the substrate and walls of the underfill resin;
transferring the substrate bonded with the semiconductor chip from under the atmospheric pressure into a vacuum;
discharging air from the air pockets in the vacuum; and
reverting the substrate bonded with the semiconductor chips from the vacuum back to the atmospheric pressure and filling the air pocket space with the underfill resin.

2. The manufacturing method of claim 1, wherein the air in the air pocket is discharged through a path formed through the underfill resin.

3. The manufacturing method of claim 2, wherein the transferring step further includes transferring the substrate into a vacuum chamber and evacuates the vacuum chamber.

4. The manufacturing method of claim 1, in which the supplying step is carried out at a first temperature that is higher than room temperature.

5. The manufacturing method of claim 4, in which the forming step is carried out at a second temperature that is higher than room temperature.

6. The manufacturing method of claim 4, in which the transferring step is carried out at a third temperature that is higher than room temperature.

7. The manufacturing method of claim 4, in which the discharging step is carried out at a fourth temperature that is higher than room temperature.

8. The manufacturing method of claim 4, in which the reverting step is carried out at a fifth temperature that is higher than room temperature.

9. The manufacturing method of claim 5, in which the first temperature is the same as the second temperature.

10. The manufacturing method of claims 1, further comprising a step following the reverting step in which the substrate with the semiconductor chip bonded thereon is maintain at a temperature that is higher than the glass transition temperature of the underfill resin.
